(19) United States
(12) Patent Application Publication
(10) Pub. No.: US 2024/0021571 A1
(43) Pub. Date: Jan. 18, 2024

(54) HYBRID BONDING OF SEMICONDUCTOR STRUCTURES TO ADVANCED SUBSTRATE PANELS

(71) Applicant: Applied Materials, Inc., Santa Clara, CA (US)

(72) Inventors: Anup PANCHOLI, Hillsboro, OR (US); Marvin Louis BERNT, Whitefish, MT (US); Ronald Patrick HUEMOELLER, Gilbert, AZ (US); Avinash SHANTARAM, Whitefish, MT (US); Vincent DICAPRIO, Pleasanton, CA (US)

(21) Appl. No.: 17/867,027

(22) Filed: Jul. 18, 2022

(51) Int. Cl. H01L 23/00; H01L 21/48

(52) U.S. Cl. CPC H01L 24/80; H01L 21/486; H01L 24/08; H01L 25/0652

(57) ABSTRACT

Methods for bonding semiconductor surfaces leverage hybrid bonding processes to enable heterogeneous integration architectures. In some embodiments, the methods may comprise forming a semiconductor structure on a silicon-based substrate with a first set of exposed conductive connections on a top surface of the semiconductor structure. The first set of exposed conductive connections having a pitch of less than approximately 10 microns. Forming an advanced rectangular substrate panel with a second set of exposed conductive connections. The second set of exposed conductive connections having a pitch of less than approximately 10 microns. Bonding a top surface of the semiconductor structure to a top surface of the advanced rectangular substrate panel using a hybrid bonding process to bond the semiconductor structure to the advanced rectangular substrate panel.

### FIELD

Embodiments of the present principles generally relate to semiconductor processing of semiconductor substrates.

### BACKGROUND

In traditional processes, semiconductor chips are manufactured in front end of the line (FEOL) processes and redistribution layers (RDLs) are formed in subsequent packaging processes to allow for electrical connections to the chip. However, the RDLs reduce the input/output (IO) density of the chips as additional space is required for connecting to the RDLs. In some instances, a fan out method of providing connections may further reduce the IO density of the chips. To allow for proper connections, similar low IO density connections are formed on a substrate to align with the RDL connections on the chip in back end of the line (BEOL) processes. The chip is then bonded to the substrate using a thermocompression bonding process and RDLs are connected to printed circuit boards (PCBs) using solder bumps. The formation of the RDLs and the reduced IO density, add to the cost and parts count of the manufacturing process. In addition, the round shape of a silicon substrate limits the effective area of the substrate on which rectangular chips that can be bonded, further increasing per unit manufacturing costs.

Accordingly, the inventors have provided methods for increasing IO density, allowing for much higher chip connection bandwidth while reducing manufacturing parts count and costs.

### SUMMARY

Architectures and methods for increasing IO connection density with hybrid bonding of chips to advanced rectangular substrate panels are provided herein.

In some embodiments, a method for bonding semiconductor surfaces may comprise, forming a first semiconductor structure on a silicon-based substrate with a first set of exposed conductive connections on a first top surface of the semiconductor structure, wherein the first set of exposed conductive connections are interspersed in a first non-conductive material layer and wherein the first set of exposed conductive connections have a pitch of less than approximately 10 microns, forming an advanced rectangular substrate panel with a second set of exposed conductive connections on a top surface of the advanced rectangular substrate panel, wherein the second set of exposed conductive connections are interspersed in a second non-conductive material layer different from the first non-conductive material layer and wherein the second set of exposed conductive connections have a pitch of less than approximately 10 microns, and bonding the first top surface of the first semiconductor structure to the top surface of the advanced rectangular substrate panel using a hybrid bonding process to directly bond the first non-conductive material layer to the second non-conductive material layer and to directly bond the first set of exposed conductive connections to the second set of exposed conductive connections.

In some embodiments, the method may further include wherein the second non-conductive material layer is polyimide, wherein the hybrid bonding process is performed at a temperature of approximately 200 degrees Celsius or less, wherein the advanced rectangular substrate panel has no core, an organic core, or a glass core, wherein the first non-conductive material layer is a first dielectric material different from a second dielectric material of the second non-conductive material layer, chemical mechanical polishing (CMP) the advanced rectangular substrate panel to a surface roughness (RA) of approximately 0.5 nm or less prior to performing the hybrid bonding process, wherein the advanced rectangular substrate panel is approximately 510 mm by approximately 515 mm, wherein the advanced rectangular substrate panel is approximately 205 mm by approximately 257.5 mm, wherein the first semiconductor structure is formed without a controlled collapse chip connection (C4) layer, wherein the first semiconductor structure is a chip or chiplet formed with a front end of the line (FEOL) process, wherein the advanced rectangular substrate panel is formed using front end of the line (FEOL) processes, and/or wherein the method is used to form a heterogeneous integration architecture on both sides of the advanced rectangular substrate panel.

In some embodiments, the method may also further include forming a second semiconductor structure on a silicon-based substrate with a third set of exposed conductive connections on a second top surface of the second semiconductor structure, wherein the third set of exposed conductive connections are interspersed in a third non-conductive material layer and wherein the third set of exposed conductive connections have a pitch of less than approximately 10 microns, forming the advanced rectangular substrate panel with a fourth set of exposed conductive connections on a bottom surface of the advanced rectangular substrate panel, wherein the fourth set of exposed conductive connections are interspersed in a fourth non-conductive material layer different from the third non-conductive material layer, and bonding the second top surface of the second semiconductor structure to the bottom surface of the advanced rectangular substrate panel using the hybrid bonding process to directly bond the third non-conductive material layer to the fourth non-conductive material layer and to directly bond the third set of exposed conductive connections to the fourth set of exposed conductive connections, wherein the first semiconductor structure bonded to the top surface of the advanced rectangular substrate and the second semiconductor structure bonded to the bottom surface of the advanced rectangular substrate are in high bandwidth electrical communication.

In some embodiments, a method for bonding semiconductor surfaces may comprise forming a semiconductor structure on a silicon-based substrate with a first set of exposed conductive connections on a top surface of the semiconductor structure, wherein the first set of exposed conductive connections are interspersed in a first non-conductive material layer and wherein the semiconductor structure is a chip or chiplet formed with front end of the line (FEOL) processes without a controlled collapse chip connection (C4) layer, forming an advanced rectangular substrate panel with a second set of exposed conductive connections on a top surface of the advanced rectangular substrate panel, wherein the second set of exposed conductive connections are interspersed in a second non-conductive material layer different from the first non-conductive material layer, and bonding the top surface of the semiconductor structure to the top surface of the advanced rectangular substrate panel using a hybrid bonding process to directly bond the first non-conductive material layer to the second non-conductive material layer and to directly bond the first set of exposed conductive connections to the second set of exposed conductive connections.

In some embodiments, the method may further include wherein the first set of exposed conductive connections have a pitch of less than approximately 10 microns and wherein the second set of exposed conductive connections have a pitch of less than approximately 10 microns, wherein the hybrid bonding process is performed at a temperature of approximately 200 degrees Celsius or less, and/or wherein the advanced rectangular substrate panel has no core, an organic core, or a glass core.

In some embodiments, a non-transitory, computer readable medium having instructions stored thereon that, when executed, cause a method for bonding semiconductor surfaces to be performed, the method may comprise forming a semiconductor structure on a silicon-based substrate with a first set of exposed conductive connections on a top surface of the semiconductor structure, wherein the first set of exposed conductive connections are interspersed in a first non-conductive material layer and wherein the first set of exposed conductive connections have a pitch of less than approximately 10 microns, forming an advanced rectangular substrate panel with a second set of exposed conductive connections on a top surface of the advanced rectangular substrate panel, wherein the second set of exposed conductive connections are interspersed in a second non-conductive material layer different from the first non-conductive material layer and wherein the second set of exposed conductive connections have a pitch of less than approximately 10 microns, and bonding the top surface of the semiconductor structure to the top surface of the advanced rectangular substrate panel using a hybrid bonding process to directly bond the first non-conductive material layer to the second non-conductive material layer and to directly bond the first set of exposed conductive connections to the second set of exposed conductive connections.

In some embodiments, the method of the non-transitory, computer readable medium may further include chemical mechanical polishing (CMP) the advanced rectangular substrate panel to a surface roughness (RA) of approximately 0.5 nm or less prior to performing the hybrid bonding process or activating the top surface of the advanced rectangular substrate panel using a plasma process, wherein the semiconductor structure is a chip or chiplet formed with a front end of the line (FEOL) process without a controlled collapse chip connection (C4) layer, and/or wherein the advanced rectangular substrate panel is formed using front end of the line (FEOL) processes.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 depicts a top-down view and a cross-sectional view of a traditional round silicon substrate.

FIG. 2 depicts a top-down view and a cross-sectional view of an advanced rectangular substrate panel in accordance with some embodiments of the present principles.

FIG. 3 depicts a cross-sectional view of a traditional semiconductor structure and a traditional silicon substrate.

FIG. 4 depicts a cross-sectional view of a semiconductor structure and an advanced rectangular substrate panel in accordance with some embodiments of the present principles.

FIG. 5 depicts a method of hybrid bonding of a semiconductor structure to an advanced rectangular substrate panel in accordance with some embodiments of the present principles.

FIG. 6 depicts a heterogeneous integration architecture enabled by the method of hybrid bonding in accordance with some embodiments of the present principles.

FIG. 7 depicts a cross-sectional view of a semiconductor structure connected to a silicon substrate via an interposer.

FIG. 8 depicts a cross-sectional view an example semiconductor device in accordance with some embodiments of the present principles.

FIG. 9 is a method of forming semiconductor architectures using a double-sided advanced rectangular substrate in accordance with some embodiments of the present principles.

FIGS. 10A-10J depict cross-sectional views of a double sided advanced rectangular substrate in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods provide a high-quality hybrid bonding process to attach individual chips or chiplets directly to a packaging substrate such as an advanced rectangular substrate panel at very high density (e.g., pitch less than 10 microns), enabling advanced architectures for semiconductor manufacturing. The present principles enable direct chip-to-substrate integration at ultra-fine pitches, eliminate the need for using interposers for chip-to-chip and chip-to-substrate to printed circuit board (PCB) interconnects, and enable multi-chip modules with high bandwidth chip-to-chip and chip-to-substrate communications. In addition, the methods and architectures provide the benefit of smaller interconnect lengths without underfill (UF) and/or interface materials to enhance reliability, thermal efficiency, and minimize resistance/capacitance (RC) losses and the like (i.e., minimal interface materials). By enabling the use of advanced rectangular substrate panels, the substrate area is maximized (e.g., rectangular/square chips to rectangular/square substrates versus rectangular/square chips to circular substrates, etc.). Such panels also afford an economy of scale in processing larger areas compared to silicon wafers.

Traditional processes use solder assisted flip-chip processes with a traditional chip attached using thermocompression bonding (TCB) at a much larger pitch. Use of underfill in traditional processes is common between the solder bumps as a dielectric and for mechanical stability. The traditional wirebond/flip chip structures have long interconnect lengths, yielding high impedance, joules heating, and RF interference, and the like with limited input/output (IO) density. The methods of the present principles use a direct molecular bonding process for the non-conductive interfaces and the conductive interfaces of chips to the advanced rectangular substrate panel. Enablement of such bonding processes is accomplished through surface roughness reduction, design optimization, and material selection. The reduced interface lengths afforded by the present principles provide better electrical performance and substantially higher IO densities. Since no underfill is required with hybrid bonding, the mechanical reliability is greatly increased. The enhanced processes also enable potential reduction of the number of metal layers or redistribution layers (RDLs) on a chip (e.g., elimination of the “C4” or controlled collapse chip connection layer on the chip, at a minimum, is possible, etc.). Similarly, the enhanced processes have the potential for reducing the number of process steps in a packaging process, reducing packaging time (i.e., improving cycle time). The present principles also afford greater flexibility in design for chip-to-substrate integration and improved electrical performance (e.g., direct copper-to-copper bonds with minimal to no electrical metallurgical interference, etc.).

The architectures and methods of the present principles leverage advanced substrates and hybrid bonding to form high bandwidth, high reliability, and high-density semiconductor chip packages. Hybrid bonding is a process where a chip is bonded directly to a substrate with, for example but not limited to, direct metal-to-metal interconnect bonding and direct non-conductive-to-non-conductive material bonding between the chip and the substrate. The non-conductive materials that are bonded together may be the same material or different materials. An annealing process may then be used to bond the metal-to-metal contacts. In some embodiments, the metal contacts may be recessed below an uppermost surface of the non-conductive material and the annealing process expands the metal in the metal contacts to overcome the recess and bond the contacts. In some embodiments, the metal contacts may be approximately level with the uppermost surface of the non-conductive material and annealing processes after bonding may not be required.

The present principles leverage the use of advanced rectangular substrate panels to facilitate in achieving high IO density connections. The high IO density connections enable the advanced architectures disclosed herein. The advanced rectangular substrate panels have non-silicon cores that are formed into rectangular panels. The connections of the advanced rectangular substrate panels may be formed with processes associated with front end of the line (FEOL) fabrication processes. The semiconductor structures used herein are typically structures that are formed during FEOL manufacturing which require high precision and complex manufacturing and then packaged together with other structures or chips in a back end of the line (BEOL) process which involves simpler processing with a much lower precision.

In the industry, FEOL semiconductor manufacturers are tooled for standard round silicon substrates and panel producers are not set up to perform FEOL processing. The architectures described herein using the present principles will require substantial investments in tooling and dramatic changes in overall semiconductor manufacturing process flows to enable such high IO density and high bandwidth device manufacturing.

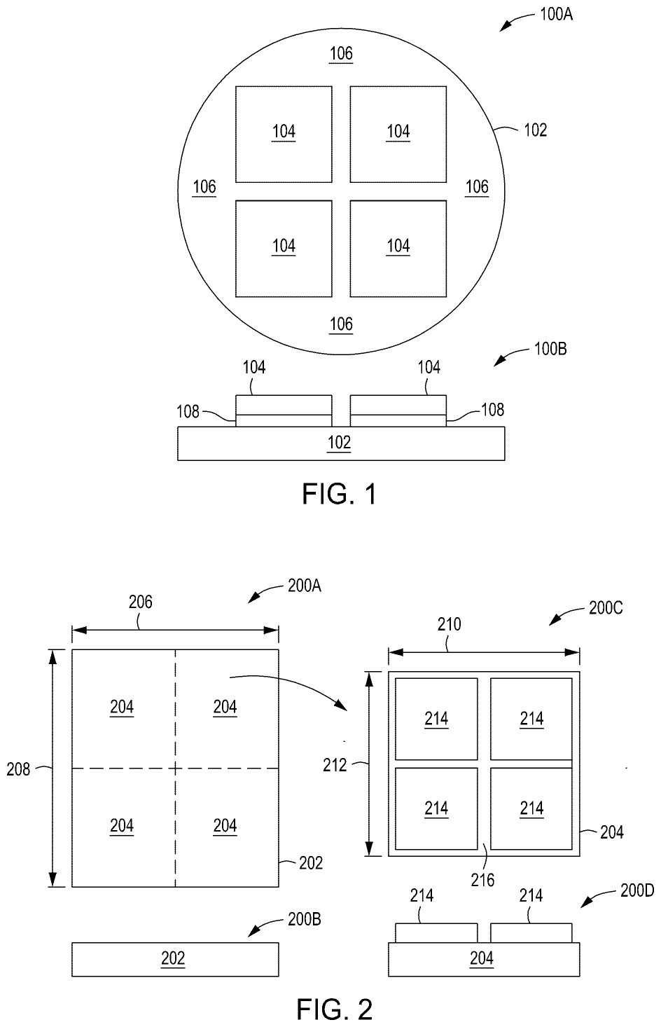

FIG. 1 is a top-down view 100A of semiconductor structures 104 such as chips or chiplets and the like that are positioned on a silicon substrate 102 with a round shape. Since the semiconductor structures 104 are rectangular and the silicon substrate 102 is round, a substantial amount of a surface area 106 of the silicon substrate 102 is wasted due to shape mismatch. In addition, the semiconductor structures 104 typically utilize an interposer 108 to allow the semiconductor structures 104 to be attached to the silicon substrate 102 as depicted in a cross-sectional view 100B of FIG. 1. A cross-sectional view 700 of FIG. 7 is an enlarged view of the connections between the semiconductor structures 104, the interposer 108, and the silicon substrate 102. The interposer 108 takes the higher density connections 702 of the circuitry from within the semiconductor structure 104 and expands (makes the connections less dense) to form interposer substrate connections 704. The interposer substrate connections 704 are typically solder ball connections. The interposer 108 is very expensive to manufacture and the intricacies of the interconnections between the semiconductor structure 104 and the silicon substrate 102 require high precision which is difficult and time consuming to achieve.

In some embodiments of the methods of the present principles, a full substrate panel 202 may be utilized as an advanced rectangular substrate panel as depicted in a top-down view 200A of FIG. 2. In some embodiments, the full substrate panel 202 may have a width 206 of approximately 510 mm and a length 208 of 515 mm and the like. In some embodiments, the full substrate panel may have a width 206 larger than approximately 510 mm and a length larger than approximately 515 mm. A cross-section of the full substrate panel 202 is depicted in view 200B. In some embodiments, the full substrate panel 202 may be cut into a quarter substrate panel 204 to permit easier handling and/or to fit into manufacturing apparatus and the like. In some embodiments, the quarter substrate panel 204 has a width 210 of approximately 255 mm and a length 212 of approximately 257.5 mm and the like (depending on the dimensions of a full substrate panel 202). In a top-down view 200C of FIG. 2, the quarter substrate panel 204 is depicted with four semiconductor structures 214 to show the substantial decrease in wasted surface area 216 of a flat substrate panel as opposed to a silicon substrate 102. A cross-sectional view 200D depicts the quarter substrate panel 204 with the semiconductor structures 214 mounted directly to the quarter substrate panel 204 without the use of interposers and the like as commonly found with silicon substrates, dramatically reducing material costs and manufacturing time.

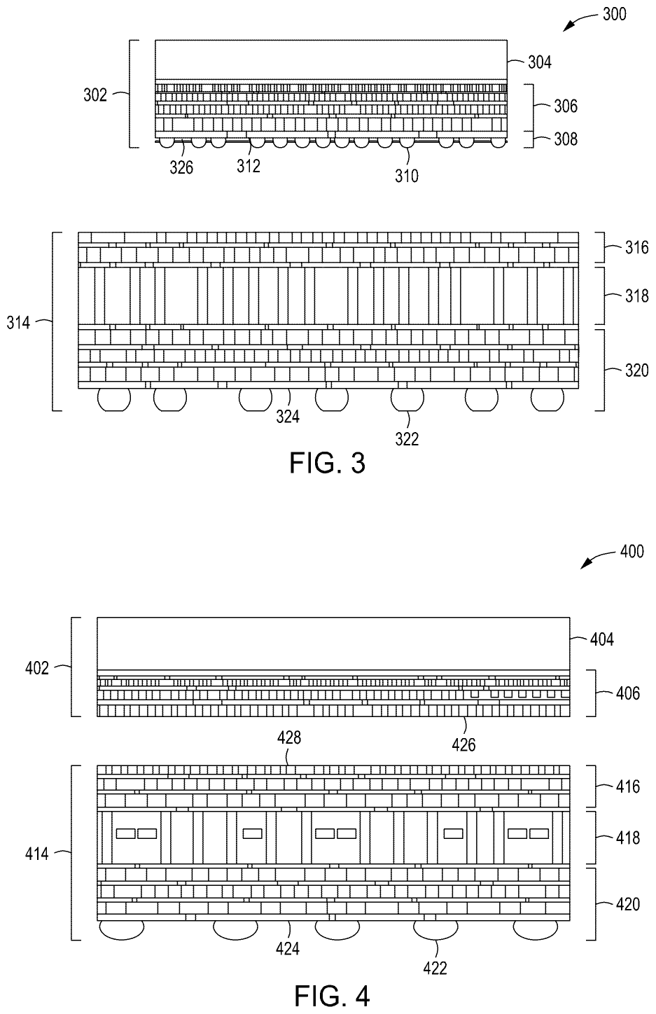

In a view 300 of FIG. 3, a semiconductor structure 302 on bulk silicon 304 includes FEOL structures 306 and a C4 layer 308 which includes RDLs 312 and solder bumps 310. Underfill 326 is used between the solder bumps 310 to stabilize the solder bumps and requires extra processing, time, and costs to form on the semiconductor structure 302. A silicon substrate 314 is formed with an interface layer 316 to interface with the C4 layer 308 of the semiconductor structure 302. Through silicon vias (TSVs) 318 provide internal connections to backside connections 320 which incorporate RDLs 324 and solder bumps 322 to allow connectivity of the silicon substrate to a PCB (not shown) and the like. Connectivity between the semiconductor structure 302 and the silicon substrate 314 is accomplished by the solder bumps 310 and the RDLs 312 on the semiconductor structure 302. The RDLs 312 expand the connections to the FEOL structures 306, typically in a fan-out layout that increases the connectivity area (decreasing the density of connections) to allow connection with the silicon substrate 314 that also includes RDLs in the interface layer 316 to allow connectivity with the semiconductor structure 302. Thus, both the semiconductor structure 302 and the silicon substrate 314 have expanded connectivity areas and fewer connections (low IO connection density which yields low bandwidth).

The inventors have observed the low connection densities of the traditional semiconductor structures to silicon substrate attachments and found that using an advanced rectangular substrate panel in lieu of silicon substrates would facilitate in increasing the usable chip placement area over traditional silicon substrates and enable new advanced architectures. In addition, the inventors also observed that the C4 layer of a traditionally formed semiconductor structure drastically reduced IO connection density. In a cross-sectional view 400 of FIG. 4, according to the present principles, FEOL structures 406 of a semiconductor structure 402 are formed on bulk silicon 404 without any C4 layers. Direct connections to the FEOL structures 406 are left exposed on a top surface 426 of the semiconductor structure 402. By eliminating C4 layers, no underfill or other supporting dielectric is required as no RDLs and solder bumps are needed when using the methods and architectures of the present principles. The elimination of the C4 layers decreases process time and costs while allowing increased IO density. In some embodiments, the pitch may be less than approximately 10 microns on the top surface 426 of the semiconductor structure 402, dramatically increasing the IO density of the semiconductor structure 402.

The inventors found that using an advanced rectangular substrate panel 414 formed using FEOL processes would allow similar IO densities as that achievable with the semiconductor structure 402, negating the need for an interposer between the semiconductor structure 402 and a printed circuit board. In some embodiments, the advanced rectangular substrate panel 414 is a non-silicon-based substrate panel such as, but not limited to, an organic-based substrate panel, a glass-based substrate panel, and/or non-core substrate panel and the like that is capable of being FEOL processed to yield orders of magnitude higher IO densities than traditional silicon-based substrates such as substrates used for BEOL packaging processes. The use of ultra-smooth core materials in the advanced rectangular substrate panel 414 helps to further increase the IO densities by decreasing the pitch.

In some embodiments, the advanced rectangular substrate panel 414 has a core 418 which may contain through core vias (TCV) 430 to transfer connections from high IO density layers 416 to PCBs via a connection layer 420 which may include RDLs 424 and solder bumps 422. The panel top surface 428 has exposed connections with IO densities matching or greater than the IO densities of the top surface 426 of the semiconductor structure 402. In some embodiments, the advanced rectangular substrate panel 414 may be formed using organic materials to electrically isolate high density IO connections. For example, but not limited to, polymers may be used such as polyimides and the like. Thus, the inventors were highly challenged to provide a process that would allow bonding of non-organic materials such as dielectrics used in the semiconductor structures to organic materials such as polyimides and the like used in the advanced rectangular substrate panel 414. In some embodiments, dielectric material used for electrical isolation may be provided by Ajinomoto Build-up Film® (ABF) and the like for the advanced rectangular substrate panel 414.

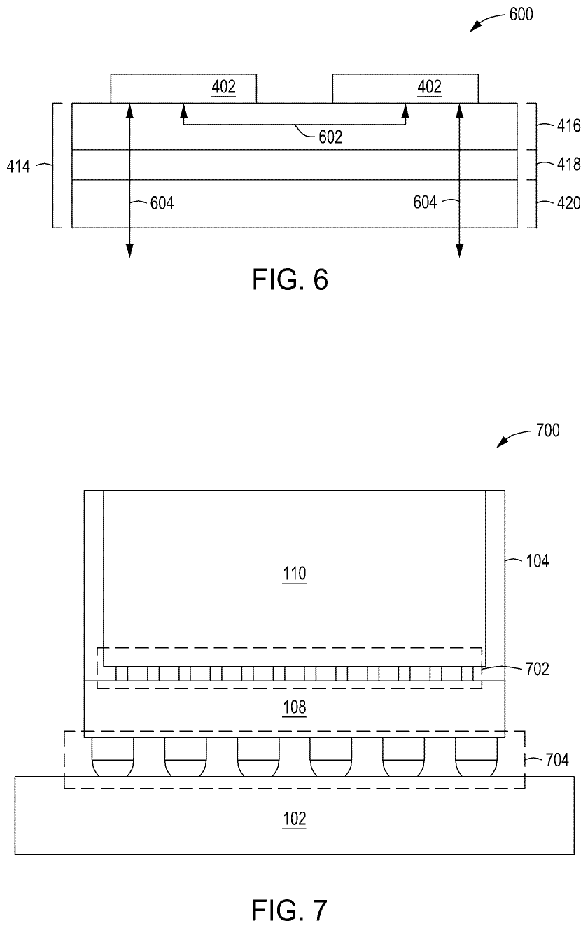

The inventors have found that with the ultra-high IO densities and high bandwidth achievable between the semiconductor structure 402 and the advanced rectangular substrate panel 414, a new chip functionality architecture based on heterogeneous integration is attainable as depicted in a cross-sectional view 600 of FIG. 6. A heterogeneous integration architecture allows the functionality of traditional chip devices to be federated between multiple chips which are interconnected with high bandwidth connections 602 in the high IO density layers 416 of the advanced rectangular substrate panel 414. The speed and bandwidth needed for a heterogeneous integration architecture is now possible using the methods of the present principles. Chips can be manufactured in different fab facilities to allow optimum manufacturing of different aspects of what used to be a single chip—that may have had performance compromises due to the need to produce all of the functionality in a single chip (e.g., reduced space, thermal loads, etc.). The present principles, given the high IO densities and high bandwidth, overcome the need to produce all functionality in a single chip without the traditional penalties (low bandwidth and high latency, etc.). In some embodiments, the advanced rectangular substrate panel 414 provides both high IO density layers 416 that may be used for high bandwidth connections 602 between chips and provides connection layers 420 to allow external IO connections 604 to allow the federated chips to connect with PCBs and the like.

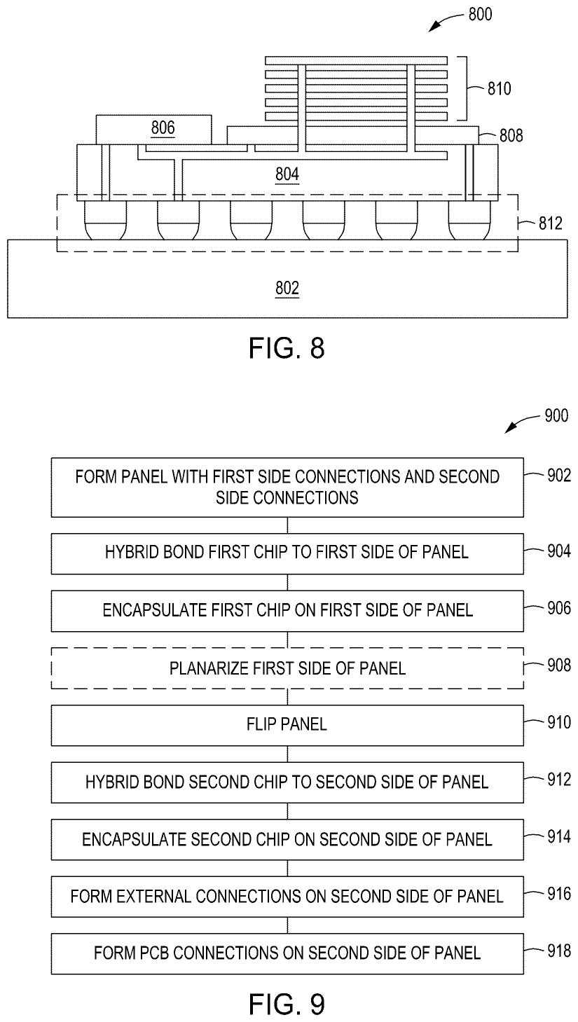

In a view 800 of FIG. 8, an example architecture using the above present principles is depicted. A first semiconductor structure, such as a graphics processing unit (GPU) 806, is hybrid bonded to an advanced rectangular substrate panel 804 along with a second semiconductor structure, such as a logic die 808 with stacked dynamic random-access memory (DRAM) 810. The advanced rectangular substrate panel 804 allows high bandwidth communication between the GPU 806, the logic die 808, and the stacked DRAM 810. In addition, the advanced rectangular substrate panel 804 allows communications with a PCB 802 via solder bumps 812 on an opposite side of the semiconductor structures. Not only does the architecture produce dramatic communication increases between semiconductor structures, but the overall process of manufacturing the device has fewer process steps and lower costs than with traditional architecture processes. One of the factors in reducing costs is that a rectangular panel can achieve 50% or more of less substrate waste due to matching of rectangular substrate structures to a rectangular panel. In addition, typically, six or more additional processes are required for round silicon wafer processing than for a single advanced rectangular substrate panel during manufacturing of semiconductor devices.

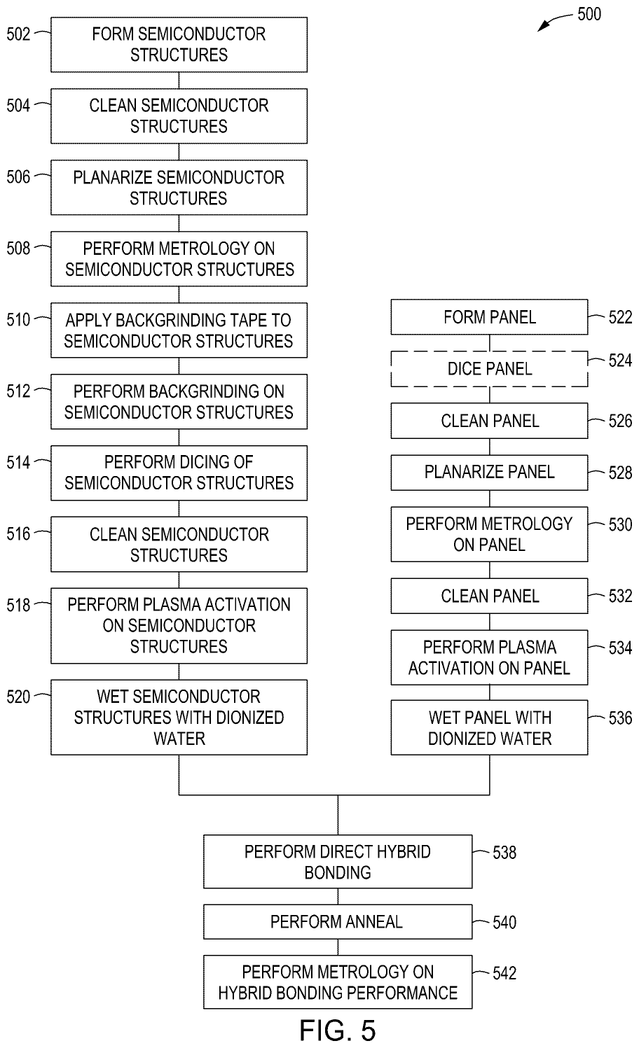

A method 500 for forming and hybrid bonding of semiconductor structures and advanced rectangular substrate panels is depicted in FIG. 5. The semiconductor structures and the advanced rectangular substrate panel formation and preparation for hybrid bonding may occur in previous processes, sequentially, in parallel, or as a combination before hybrid bonding. In block 502, a semiconductor structure is formed with direct connectivity to the underlying structures, for example, without C4 layers and the like which decrease IO density. In some embodiments, the semiconductor structures may be formed with IO densities of approximately 10,000 IO's per mm 2 or more. The semiconductor structure is typically formed using FEOL processes and may be formed on bulk silicon and the like using conductive materials such as, but not limited to, copper and/or aluminum, etc. and/or non-conductive materials (e.g., dielectric materials) such as, but not limited to, silicon dioxide (SiO₂), silicon carbon nitride (SiCN), and the like. In block 504, the semiconductor structures are wet cleaned to reduce particulates from formation processes.

In block 506, the semiconductor structures are planarized using chemical mechanical processes (CMP) to allow high density IO connectivity. The planarization process permits pitches of approximately 10 microns or less. In some embodiments, the semiconductor structures are planarized to a surface roughness or RA of approximately 01.0 nm or less per 10 mm×10 mm area. In some embodiments, the semiconductor structures are planarized to a surface roughness or RA of approximately 0.5 nm or less per 10 mm×10 mm area. In block 508, metrology is performed on the semiconductor structures to determine if any defects exist such as dishing and other defects. In block 510, a backgrinding tape is applied to the semiconductor structures to prepare the semiconductor structures for backgrinding. In block 512, a backgrinding process is performed on the semiconductor structures to reduce the thickness of the semiconductor structures by removing portions of the bulk silicon on which the semiconductor structures are formed. In block 514, the semiconductor structures are diced/separated/singulated to allow each of the semiconductor structures to be picked, placed, and bonded individually. In block 516, the semiconductor structures undergo another cleaning process to remove any particulates generated by the prior processes. In block 518, the semiconductor structures undergo plasma activation to prepare the semiconductor structures for hybrid bonding. In block 520, the semiconductor structures are wetted with deionized water prior to undergoing the hybrid bonding process with an advanced rectangular substrate panel.

As noted above, the processes 522-536 for preparing the advanced rectangular substrate panel for hybrid bonding may occur in parallel with, prior to, or after processes 502-520 for preparing the semiconductor substrates. In block 522, the advanced rectangular substrate panel is formed. The formation is generally several processes that produce the final advanced rectangular substrate panel. Non-conductive materials used in a bonding surface of the advanced rectangular substrate panel to be bonded with a bonding surface of a semiconductor structure may be the same as the non-conductive materials in the bonding surface of the semiconductor structure or different from the non-conductive materials in the bonding surface of the semiconductor structure. As no packaging processes such as RDLs and solder bumps are required for hybrid bonding of the advanced rectangular substrate panel to the semiconductor structure, the advanced rectangular substrate panel may be formed wholly or at least in part by FEOL processes. In some embodiments, the formation processes may include forming a full substrate panel and/or forming a full substrate panel and then reducing the full substrate panel to quarter substrate panels and the like. Thus, as used herein in the method 500, an advanced rectangular substrate panel may be a full substrate panel or a portion of a full substrate panel (e.g., a quarter panel, etc.).

In some embodiments, a full substrate panel may be approximately 510 mm by approximately 515 mm or may be larger or smaller in size. In optional block 524, a full substrate panel may be diced or cut into smaller portions such as a quarter substrate panel and the like. In some embodiments, a quarter substrate panel may be approximately 205 mm by approximately 257.5 mm or smaller/larger based on the size of the full substrate panel. In some embodiments, a full substrate panel may also be cut into greater than four smaller panels (e.g., one large panel cut into 6, 8, or 10 or more smaller panels, etc.). In block 526, the advanced rectangular substrate panel is cleaned to remove any residue and/or particulates generated. In block 528, the advanced rectangular substrate panel is planarized. The planarization process of a rectangular substrate panel differs from planarization of a circular substrate such as the substrates used in the formation of the semiconductor structures during FEOL processes. The planarization of a rectangular substrate panel requires advanced CMP processes similar to processes used for FEOL that achieve a surface roughness or RA of approximately 1.0 nm or less to allow a pitch of approximately 10 microns or less.

In some embodiments, the CMP processes yield a surface roughness or RA of approximately 0.5 nm or less. The RA is typically achieved over a surface area of the advanced rectangular substrate panel associated with a reticle's field of view which is a surface area of approximately 10 mm by 10 mm. In some embodiments, a total thickness variation of the advanced rectangular substrate panel after planarization may be 1 micron or less between minimum thickness and maximum thickness of the panel. As semiconductor structures that are hybrid bonded to the advanced rectangular panel are typically much smaller in surface area than the panel, localized surface roughness of the panel is more critical than overall global surface quality of the panel for hybrid bonding. Because the advanced rectangular substrate panel is not round, polishing surfaces for CMP are typically rotating and care must be taken to protect the edges of the rectangular panels during CMP processing. Specialized jigs may be used to protect the edges and maintain overall panel thicknesses.

In block 530, metrology is performed on the advanced rectangular substrate panel to detect defects such as, but not limited to, dishing and the like of the substrate panel. In block 532, the advanced rectangular substrate panel is cleaned to remove any residue and/or particulates. In block 534, the advanced rectangular substrate panel undergoes a plasma activation process to prepare the advanced rectangular substrate panel for hybrid bonding to a semiconductor structure. In some embodiments, the advanced rectangular substrate panel may use a different plasma activation process than that used for the semiconductor substrate due to the use of alternate materials such as polymers and the like which have higher temperature sensitivities. In some embodiments, the plasma used in the activation process may be less intense for polymer-based materials than for non-polymer-based materials. The plasma activation process performs the activation at a temperature near room temperature of approximately 15 degrees Celsius to approximately 25 degrees Celsius. In block 536, in some instances, the advanced rectangular substrate panel may be wetted with deionized water. In other instances, other ionic solutions may be used to wet the advanced rectangular substrate panel so as not to passivate the materials used in the advanced rectangular substrate panel.

In block 538, the semiconductor structure is picked and placed on the advanced rectangular substrate panel in a hybrid bonding process between the semiconductor structure and the advanced rectangular substrate panel. In block 540, an anneal process is performed to complete the hybrid bonding process by expanding the metal surface connections on the semiconductor structure and the advanced rectangular substrate panel until the surface connections bond together. A coefficient of linear thermal expansion (CTE) for metallic materials used in the semiconductor substrate and the advanced rectangular substrate panel may be used to determine parameters required for joining of the metallic materials. In some embodiments, the metal contacts may be approximately level with an uppermost (or lowermost) surface of the non-conductive material and annealing processes after hybrid bonding may not be required.

If organic materials are used in the advanced rectangular substrate panel such as, but not limited to, polymers and the like, the hybrid bonding process temperatures may be limited. In some embodiments, the annealing process may be limited to a process temperature of approximately 90 degrees Celsius to approximately 200 degrees Celsius to protect the integrity of some types of non-conductive materials (e.g., polymer-based materials, etc.). The inventors have found that by using processes such as selective laser annealing, microwave annealing, and/or a high-pressure environment and the like, lower annealing temperatures can be achieved as needed to preserve materials used in the advanced rectangular substrate panel. In block 542, metrology is performed on the hybrid bonding to detect any defects such as misalignment and/or bonding voids and the like.

The architectures and methods of the present principles described above may be further modified to produce advanced rectangular substrate panels with high density connections on both sides of the substrate panels. FEOL processing is used to form the high-density connections on both sides to allow for high bandwidth processing between semiconductor structures bonded on the same side and also with semiconductor substructures bonded on an opposite side, dramatically increasing the possible chip density of a single advanced rectangular substrate panel. Such high IO densities and chip densities with high bandwidth connections allow for a tremendous increase in the performance of products such as advanced supercomputers and the like. FEOL processing of both sides of the advanced rectangular substrate panel increases the production costs of the panel and may be more suitable for low volume, extreme performance products and the like.

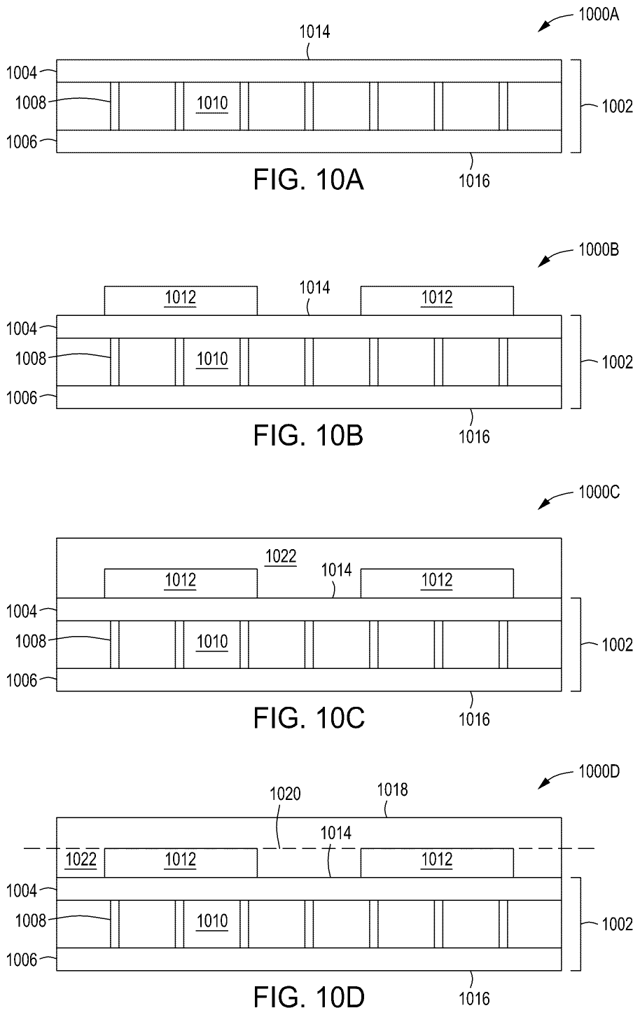

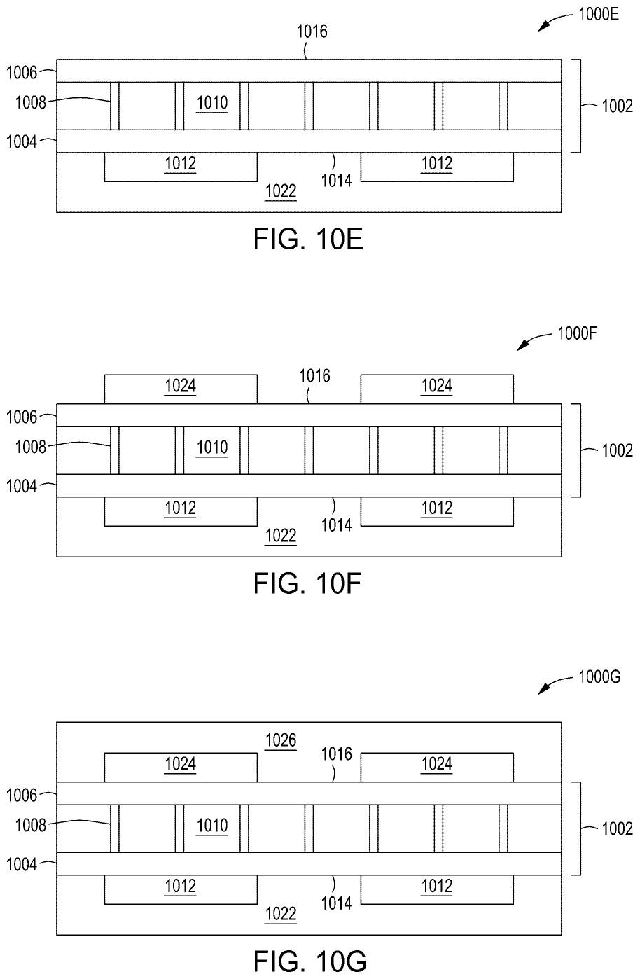

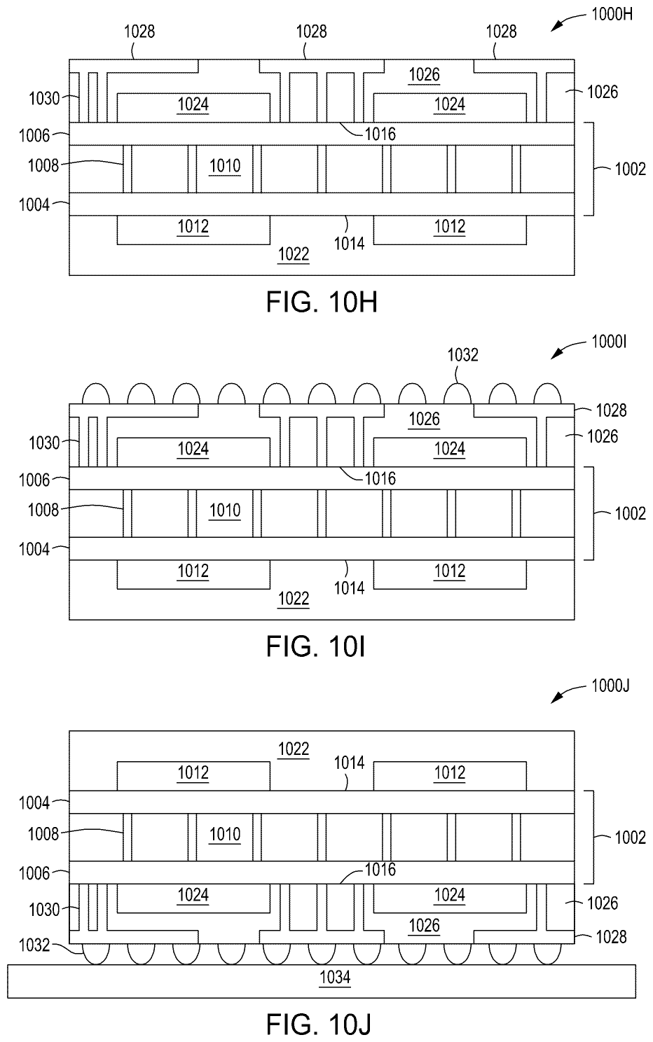

FIG. 9 depicts a method 900 of forming double-sided advanced rectangular substrate panels with interconnected semiconductor structures on both sides. Views 1000A to 1000J of FIG. 10 may be referenced during the discussion of the method 900. In block 902, an advanced rectangular substrate panel 1002 (see FIG. 10A) is formed with first side connections 1004 on a first side 1014 (e.g., a top side) and second side connections 1006 on a second side 1016 (e.g., a bottom side). The first side connections 1004 and the second side connections 1006 are high IO density connections that allow high bandwidth connections on each side. Through core vias (TCVs) 1008 are formed to connect the first side connections 1004 to the second side connections 1006 through the core 1010 of the advanced rectangular substrate panel 1002. The first side connections 1004 are formed using FEOL processes as described above for single sided panels. The second side connections 1006 are formed using FEOL processes as described above for single sided panels. The first side connections 1004 and the second side connections 1006 may be formed with IO densities of approximately 10,000 IO's per mm 2 or more and with interconnecting TCVs.

In block 904, at least one first semiconductor structure 1012 (e.g., a chip, chiplet, etc.) is hybrid bonded to the first side 1014 of the advanced rectangular substrate panel 1002 as depicted in a view 1000B of FIG. 10B. The hybrid bonding process is described above for the single sided advanced rectangular substrate and the semiconductor structure. After bonding has occurred, the IO connections of the at least one first semiconductor structure 1012 are connected to the IO connections of the first side connections 1004 and are available for high bandwidth connections to other semiconductor structures on the first side 1014 and also to the second side 1016 through the TCVs. In block 906, the at least one first semiconductor structure 1012 on the first side 1014 is encapsulated with a first encapsulation material 1022 as depicted in a view 1000C of FIG. 10C. The first encapsulation material 1022 protects the at least one first semiconductor structure 1012 during subsequent processing and may also provide a base for mounting a carrier (not shown) to the first side 1014 of the advanced rectangular substrate panel 1002 to provide stability for further processing. The first encapsulation material 1022 may be a molding type material and/or a dielectric type material and the like.

In optional block 908, an upper surface 1018 of the first encapsulation material 1022 may be planarized in a CMP process as depicted in a view 1000D of FIG. 10D. In some embodiments, the planarizing may be performed to level the upper surface 1018 for application of a carrier and the like for subsequent handling and processing. In some embodiments, the planarizing may remove the first encapsulation material 1022 to a level 1020 that exposes one or more uppermost surfaces of the at least one first semiconductor structure 1012 to enable placement of thermal control apparatus and like (e.g., thermal pads, thermal tape, thermal heatsinks, etc.). In block 910, the advanced rectangular substrate panel 1002 is flipped so that the second side 1016 is on top and the first side 1014 is on bottom as depicted in a view 1000E of FIG. 10E. In block 912, at least one second semiconductor structure 1024 (e.g., a chip, chiplet, etc.) is hybrid bonded to the second side 1016 of the advanced rectangular substrate panel 1002 as depicted in a view 1000F of FIG. 10F. The hybrid bonding process is described above for the single sided advanced rectangular substrate and the semiconductor structure. After bonding has occurred, the IO connections of the at least one second semiconductor structure 1024 are connected to the IO connections of the second side connections 1006 and are available for high bandwidth connections to other semiconductor structures on the second side 1016 and also to the first side 1014 through the TCVs.

In block 914, the at least one second semiconductor structure 1024 on the second side 1016 is encapsulated with a second encapsulation material 1026 as depicted in a view 1000G of FIG. 10G. The second encapsulation material 1026 protects the at least one second semiconductor structure 1024 during subsequent processing and may also provide a base for constructing external connections (e.g., vias, RDLs, etc.) to the second side 1016 of the advanced rectangular substrate panel 1002. In some embodiments, the first encapsulation material 1022 and the second encapsulation material 1026 may be the same material or different. The second encapsulation material 1026 may be a molding type material and/or a dielectric type material and the like. In block 916, external connections 1028 are formed on the second side 1016 of the advanced rectangular substrate 1002 as depicted in a view 1000H of FIG. 10H. The external connections 1028 may include RDLs and through mold vias (TMVs) 1030 that provide connection to the second side connections 1006 and subsequently to the first side connections 1004 through the TCVs 1008. In some embodiments, the second encapsulation material 1026 may be planarized in a CMP process to allow for fine pitch RDL formation.

In block 918, PCB connections 1032 (e.g., solder balls, etc.) are formed on the second side 1016 of the advanced rectangular substrate panel 1002 as depicted in a view 1000I of FIG. 10I. The PCB connections 1032 enable external connections to be made to the at least one first semiconductor structure 1012 and/or to the at least one second semiconductor structure 1024 and the like. In a view 1000J of FIG. 10J, the advanced rectangular substrate panel 1002 has been flipped and mounted to a PCB 1034. The architecture of the present principles allows an assembly to be constructed with high bandwidth capabilities between semiconductor structures on each side and between sides of an advanced rectangular substrate panel 1002 while maintaining compatibility with PCB type external connections and with less parts (e.g., no interposers, etc.), increasing reliability and performance. In effect, the architecture will enable heterogeneous integration architectures and the next generation of supercomputers.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method for bonding semiconductor surfaces, comprising:
forming a first semiconductor structure on a silicon-based substrate with a first set of exposed conductive connections on a first top surface of the first semiconductor structure, wherein the first set of exposed conductive connections are interspersed in a first non-conductive material layer and wherein the first set of exposed conductive connections have a pitch of less than approximately 10 microns;
forming an advanced rectangular substrate panel with a second set of exposed conductive connections on a top surface of the advanced rectangular substrate panel, wherein the second set of exposed conductive connections are interspersed in a second non-conductive material layer different from the first non-conductive material layer and wherein the second set of exposed conductive connections have a pitch of less than approximately 10 microns; and
bonding the first top surface of the first semiconductor structure to the top surface of the advanced rectangular substrate panel using a hybrid bonding process to directly bond the first non-conductive material layer to the second non-conductive material layer and to directly bond the first set of exposed conductive connections to the second set of exposed conductive connections.

2. The method of claim 1, wherein the second non-conductive material layer is polyimide.

3. The method of claim 1, wherein the hybrid bonding process is performed at a temperature of approximately 200 degrees Celsius or less.

4. The method of claim 1, wherein the advanced rectangular substrate panel has no core, an organic core, or a glass core.

5. The method of claim 1, wherein the first non-conductive material layer is a first dielectric material different from a second dielectric material of the second non-conductive material layer.

6. The method of claim 1, further comprising:
chemical mechanical polishing (CMP) the advanced rectangular substrate panel to a surface roughness (RA) of approximately 0.5 nm or less prior to performing the hybrid bonding process.

7. The method of claim 1, further comprising:
forming a second semiconductor structure on a silicon-based substrate with a third set of exposed conductive connections on a second top surface of the second semiconductor structure, wherein the third set of exposed conductive connections are interspersed in a third non-conductive material layer and wherein the third set of exposed conductive connections have a pitch of less than approximately 10 microns;
forming the advanced rectangular substrate panel with a fourth set of exposed conductive connections on a bottom surface of the advanced rectangular substrate panel, wherein the fourth set of exposed conductive connections are interspersed in a fourth non-conductive material layer different from the third non-conductive material layer; and
bonding the second top surface of the second semiconductor structure to the bottom surface of the advanced rectangular substrate panel using the hybrid bonding process to directly bond the third non-conductive material layer to the fourth non-conductive material layer and to directly bond the third set of exposed conductive connections to the fourth set of exposed conductive connections, wherein the first semiconductor structure bonded to the top surface of the advanced rectangular substrate panel and the second semiconductor structure bonded to the bottom surface of the advanced rectangular substrate panel are in high bandwidth electrical communication.

8. The method of claim 1, wherein the advanced rectangular substrate panel is approximately 510 mm by approximately 515 mm.

9. The method of claim 1, wherein the advanced rectangular substrate panel is approximately 205 mm by approximately 257.5 mm.

10. The method of claim 1, wherein the first semiconductor structure is formed without a controlled collapse chip connection (C4) layer.

11. The method of claim 1, wherein the first semiconductor structure is a chip or chiplet formed with a front end of line (FEOL) process.

12. The method of claim 1, wherein the advanced rectangular substrate panel is formed using front end of line (FEOL) processes.

13. The method of claim 1 is used to form a heterogeneous integration architecture on both sides of the advanced rectangular substrate panel.

14. A method for bonding semiconductor surfaces, comprising:
forming a semiconductor structure on a silicon-based substrate with a first set of exposed conductive connections on a top surface of the semiconductor structure, wherein the first set of exposed conductive connections are interspersed in a first non-conductive material layer and wherein the semiconductor structure is a chip or chiplet formed with front end of line (FEOL) processes without a controlled collapse chip connection (C4) layer;
forming an advanced rectangular substrate panel with a second set of exposed conductive connections on a top surface of the advanced rectangular substrate panel, wherein the second set of exposed conductive connections are interspersed in a second non-conductive material layer different from the first non-conductive material layer; and
bonding the top surface of the semiconductor structure to the top surface of the advanced rectangular substrate panel using a hybrid bonding process to directly bond the first non-conductive material layer to the second non-conductive material layer and to directly bond the first set of exposed conductive connections to the second set of exposed conductive connections.

15. The method of claim 14, wherein the first set of exposed conductive connections have a pitch of less than approximately 10 microns and wherein the second set of exposed conductive connections have a pitch of less than approximately 10 microns.

16. The method of claim 14, wherein the hybrid bonding process is performed at a temperature of approximately 200 degrees Celsius or less.

17. The method of claim 14, wherein the advanced rectangular substrate panel has no core, an organic core, or a glass core.

18. A non-transitory, computer readable medium having instructions stored thereon that, when executed, cause a method for bonding semiconductor surfaces to be performed, the method comprising:
forming a semiconductor structure on a silicon-based substrate with a first set of exposed conductive connections on a top surface of the semiconductor structure, wherein the first set of exposed conductive connections are interspersed in a first non-conductive material layer and wherein the first set of exposed conductive connections have a pitch of less than approximately 10 microns;
forming an advanced rectangular substrate panel with a second set of exposed conductive connections on a top surface of the advanced rectangular substrate panel, wherein the second set of exposed conductive connections are interspersed in a second non-conductive material layer different from the first non-conductive material layer and wherein the second set of exposed conductive connections have a pitch of less than approximately 10 microns; and
bonding the top surface of the semiconductor structure to the top surface of the advanced rectangular substrate panel using a hybrid bonding process to directly bond the first non-conductive material layer to the second non-conductive material layer and to directly bond the first set of exposed conductive connections to the second set of exposed conductive connections.

19. The non-transitory, computer readable medium of claim 18, the method further comprising:
chemical mechanical polishing (CMP) the advanced rectangular substrate panel to a surface roughness (RA) of approximately 0.5 nm or less prior to performing the hybrid bonding process; or
activating the top surface of the advanced rectangular substrate panel using a plasma process.

20. The non-transitory, computer readable medium of claim 18,
wherein the semiconductor structure is a chip or chiplet formed with a front end of line (FEOL) process without a controlled collapse chip connection (C4) layer; or
wherein the advanced rectangular substrate panel is formed using front end of line (FEOL) processes.
